(19) United States
(12) Patent Application Publication
(10) Pub. No.: US 2025/0338513 A1
(43) Pub. Date: Oct. 30, 2025

(54) SEMICONDUCTOR DEVICE

(71) Applicant: SK hynix Inc., Gyeonggi-do (KR)

(72) Inventors: Young Ock HONG, Gyeonggi-do (KR); Eun Seok CHOI, Gyeonggi-do (KR); Dong Won KIM, Gyeonggi-do (KR); Yu Jin PARK, Gyeonggi-do (KR); Hui Woo PARK, Gyeonggi-do (KR)

(21) Appl. No.: 19/051,195

(22) Filed: Feb. 12, 2025

(30) Foreign Application Priority Data
Apr. 30, 2024 (KR) 10-2024-0057300

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08146; H01L 2924/1431; H01L 2924/14511

(57) ABSTRACT

A semiconductor device may include a first memory cell array including a first source line, a first bit line, a first memory string, and first word lines; a second memory cell array including a second source line, a second bit line, a second memory string, and second word lines; a first interconnection structure including a first through via passing through the first memory cell array and commonly connected to the first bit line and the second bit line; a second interconnection structure including a second through via passing through the first memory cell array and commonly connected to the first word line and the second word line; a page buffer selectively accessing the first memory string or the second memory string through the first interconnection structure; and a row decoder commonly controlling the first word line and the second word line through the second interconnection structure.

### CROSS-REFERENCE TO RELATED APPLICATION

This application claims priority under 35 U.S.C. § 119 to Korean Patent Application No. 10-2024-0057300 filed on Apr. 30, 2024, which is incorporated herein by reference in its entirety.

### BACKGROUND

### 1. Technical Field

Various embodiments of the present disclosure relate generally to semiconductor technology, and more particularly, to a semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, to improve the operational reliability of such a semiconductor device, various structures and manufacturing methods have been developed.

### SUMMARY

In an embodiment of the present invention, a semiconductor device may include a first memory cell array including a first source line, a first bit line, a first memory string connected between the first source line and the first bit line, the first memory string including first memory cells, and first word lines connected to the first memory cells; a second memory cell array located over the first memory cell array and including a second source line, a second bit line, a second memory string connected between the second source line and the second bit line, the second memory string including second memory cells, and second word lines connected to the second memory cells; a first interconnection structure including a first through via passing through the first memory cell array and commonly connected to the first bit line and the second bit line; a second interconnection structure including a second through via passing through the first memory cell array and commonly connected to the first word line and the second word line; a page buffer selectively accessing the first memory string or the second memory string through the first interconnection structure; and a row decoder commonly controlling the first word line and the second word line through the second interconnection structure.

In an embodiment of the present invention, a semiconductor device may include a first gate structure including stacked first word lines; a second gate structure located over the first gate structure and including stacked second word lines; a first bit line located under the first gate structure; a first source line located between the first gate structure and the second gate structure; a second bit line located between the first source line and the second gate structure; a second source line located over the second gate structure; a first through via passing through the first source line and the first gate structure and connecting the first bit line and the second bit line to each other; second through vias passing through the first gate structure and connecting the first word lines and the second word lines to each other; a page buffer commonly connected to the first bit line and the second bit line through the first through via; and a row decoder commonly controlling the first word lines and the second word lines through the second through vias.

### BRIEF DESCRIPTION OF THE DRAWINGS

FIGS. 1A to 1C are diagrams illustrating a configuration of a semiconductor device in accordance with an embodiment of the present invention.

FIGS. 2A to 2C are diagrams illustrating a configuration of a semiconductor device in accordance with an embodiment of the present invention.

FIGS. 3A to 3C are diagrams illustrating a configuration of a semiconductor device in accordance with an embodiment of the present invention.

FIGS. 4A and 4B are diagrams illustrating a configuration of a semiconductor device in accordance with an embodiment of the present invention.

FIGS. 5A to 5C are simplified diagrams of a structure of a semiconductor device in accordance with an embodiment of the present invention.

FIGS. 6A and 6B are simplified diagrams of a structure of a semiconductor device in accordance with an embodiment of the present invention.

FIGS. 7A and 7B are simplified diagrams of a structure of a semiconductor device in accordance with an embodiment of the present invention.

FIGS. 8A and 8B are diagrams illustrating a configuration of a semiconductor device in accordance with an embodiment of the present invention.

FIG. 9 is a configuration diagram of a semiconductor device in accordance with an embodiment of the present invention.

FIG. 10 is a configuration diagram of a semiconductor device in accordance with an embodiment of the present invention.

FIG. 11 is a simplified diagram of a memory system in accordance with an embodiment of the present invention.

FIG. 12 is a simplified diagram of a memory system in accordance with an embodiment of the present invention.

FIG. 13 is a simplified diagram of a memory system in accordance with an embodiment of the present invention.

FIG. 14 is a simplified diagram of a memory system in accordance with an embodiment of the present invention.

FIG. 15 is a simplified diagram of a memory system in accordance with an embodiment of the present invention.

### DETAILED DESCRIPTION

Various embodiments of the present invention are directed to a semiconductor device having a stable structure and improved characteristics.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

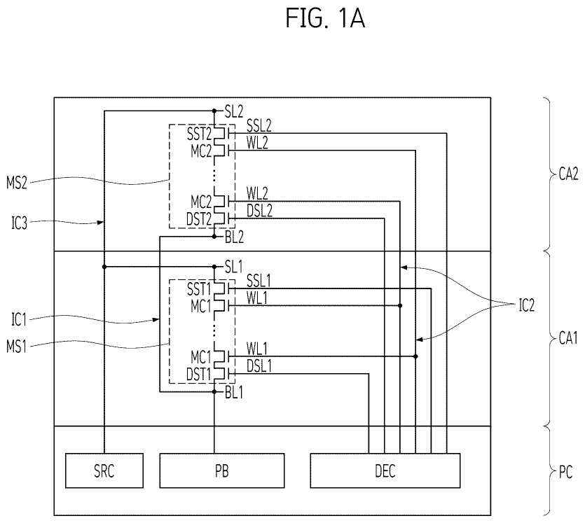

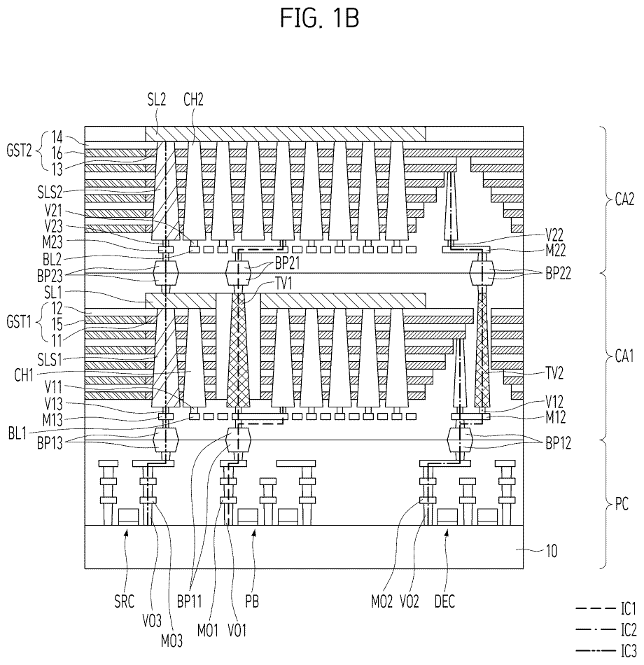

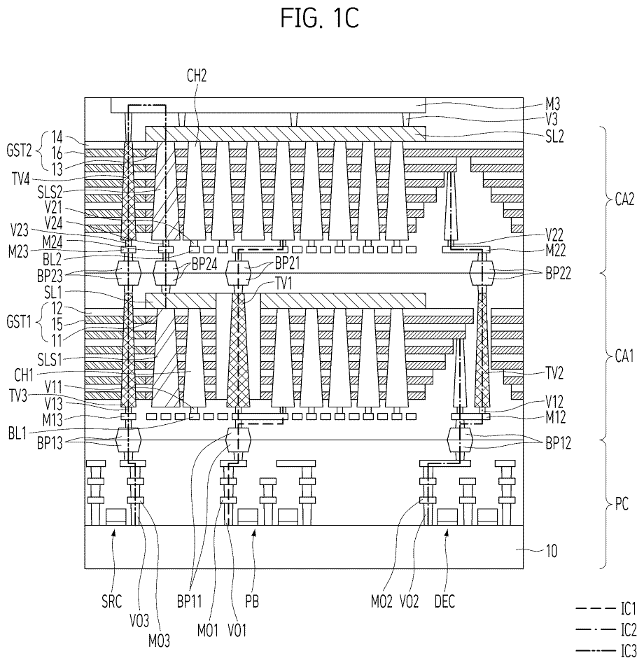

FIGS. 1A to 1C are diagrams illustrating a configuration of a semiconductor device in accordance with an embodiment of the present invention.

Referring to FIG. 1A, the semiconductor device may include a peripheral circuit PC, a first memory cell array CA1 disposed over the peripheral circuit PC, and a second memory cell array CA2 disposed over the first memory cell array. The semiconductor device may further include first, second, and third interconnection structures IC1, IC2, and IC3 that connect the first memory cell array CA1 and the second memory cell array CA2 to the peripheral circuit PC.

The first memory cell array CA1 may be located over the peripheral circuit PC. The first memory cell array CA1 may include a first source line SL1, a first bit line BL1, and a first memory string MS1 connected between the first source line SL1 and the first bit line BL1. The first memory string MS1 may include at least one first source select transistor SST1, a plurality of first memory cells MC1, and at least one first drain select transistor DST1. The first memory cell array CA1 may include a first source select line SSL1 connected to the first source select transistor SST1, first word lines WL1 connected to the first memory cells MC1, and a first drain select line DSL1 connected to the first drain select transistor DST1.

The second memory cell array CA2 may be located over the first memory cell array CA1. The second memory cell array CA2 may include a second source line SL2, a second bit line BL2, and a second memory string MS2 connected between the second source line SL2 and the second bit line BL2. The second memory string MS2 may include at least one second source select transistor SST2, a plurality of second memory cells MC2, and at least one second drain select transistor DST2. The second memory cell array CA2 may include a second source select line SSL2 connected to the second source select transistor SST2, second word lines WL2 connected to the second memory cells MC2, and a second drain select line DSL2 connected to the second drain select transistor DST2.

The first memory string MS1 of the first memory cell array CA1 and the second memory string MS2 of the second memory cell array CA2 may belong to the same memory block.

The peripheral circuit PC may include a page buffer PB, a row decoder DEC, and a source control circuit SRC. The first bit line BL1 and the second bit line BL2 may be connected to each other through the first interconnection structure IC1, and the page buffer PB may be commonly connected to the first memory string MS1 and the second memory string MS2 through the first interconnection structure IC1. Accordingly, the page buffer PB may selectively access the first memory string MS1 or the second memory string MS2. During a program operation, the page buffer PB may operate as a writer driver and may input data to be stored in the first memory cell array CA1 or the second memory cell array CA2. During a read or verify operation, the page buffer PB may operate as a sense amplifier and may output data stored in the first memory cell array CA1 or the second memory cell array CA2.

The row decoder DEC may be commonly connected to the first word lines WL1 and the second word lines WL2 through the second interconnection structures IC2 and may commonly control the first word lines WL1 and the second word lines WL2. The row decoder DEC may activate the first word lines WL1 and the second word lines WL2 according to an address.

The row decoder DEC may control each of the first source select line SSL1, the second source select line SSL2, the first drain select line DSL1, and the second drain select line DSL2. The row decoder DEC may activate the first source select line SSL1 or the second source select line SSL2 or activate the first drain select line DSL1 or the second drain select line DSL2, according to the address. Accordingly, the first memory string MS1 and the second memory string MS2 belonging to the same memory block MB may be selectively driven.

The source control circuit SRC may be commonly connected to the first source line SL1 and the second source line SL2 through the third interconnection structure IC3 and may commonly control the first source line SL1 and the second source line SL2.

Referring to FIG. 1B, the semiconductor device may include a peripheral circuit PC, a first memory cell array CA1 disposed over the peripheral circuit PC, and a second memory cell array CA2 disposed over the first memory cell array CA1. The first memory cell array CA1 may be located between the peripheral circuit PC and the second memory cell array CA2. The peripheral circuit PC and the first memory cell array CA1 may be electrically connected to each other through first bonding pads BP11, BP12, and BP13. The first memory cell array CA1 and the second memory cell array CA2 may be electrically connected to each other through second bonding pads BP21, BP22, and BP23.

The peripheral circuit PC may include a page buffer PB, a row decoder DEC, and a source control circuit SRC. As an example, the peripheral circuit PC may include a substrate 10 and at least one transistor located on the substrate 10. Vias V01, V02, and V03 and wiring lines M01, M02, and M03 may be connected to the peripheral circuit PC.

The first memory cell array CA1 may include a first gate structure GST1, a first channel structure CH1, a first bit line BL1, a first source line SL1, and a first slit structure SLS1. The first gate structure GST1 may include first conductive layers 11 and first insulating layers 12 that are alternately stacked. The first conductive layer 11 may be a first source select line SSL1, a first word line WL1, or a first drain select line DSL1. The first gate structure GST1 may include a dummy region. The dummy region may include first sacrificial layers 15 instead of the first conductive layers 11. The first sacrificial layers 15 may be layers remaining without being replaced with the first conductive layers 11 in a manufacturing process.

The first slit structure SLS1 may extend through the first gate structure GST1, and may be connected to the first source line SL1. The first slit structure SLS1 may be a source contact structure or an insulating structure. When the first slit structure SLS1 is the source contact structure, the first slit structure SLS1 may include a conductive layer electrically connected to the first source line SL1 and insulating spacers surrounding sidewalls of the conductive layer.

The first bit line BL1 may be located under the first gate structure GST1. The first source line SL1 may be located over the first gate structure GST1. The first channel structure CH1 may extend through the first gate structure GST1 and may be connected between the first bit line BL1 and the first source line SL1. A first source select transistor SST1, a first memory cell MC1, or a first drain select transistor DST1 may be located in regions where the first channel structure CH1 and the first conductive layers 11 intersect each other. The first source select transistor SST1, the first memory cell MC1, and the first drain select transistor DST1 sharing the first channel structure CH1 with each other may constitute a first memory string MS1.

The second memory cell array CA2 may include a second gate structure GST2, a second channel structure CH2, a second bit line BL2, a second source line SL2, and a second slit structure SLS2. The second gate structure GST2 may include second conductive layers 13 and second insulating layers 14 that are alternately stacked. The second conductive layer 13 may be a second source select line SSL2, a second word line WL2, or a second drain select line DSL2. The second gate structure GST2 may include a dummy region. The dummy region may include second sacrificial layers 16 instead of the second conductive layers 13. The second sacrificial layers 16 may be layers remaining without being replaced with the second conductive layers 13 in a manufacturing process.

The second slit structure SLS2 may extend through the second gate structure GST2 and may be connected to the second source line SL2. The second slit structure SLS2 may be a source contact structure or an insulating structure. When the second slit structure SLS2 is the source contact structure, the second slit structure SLS2 may include a conductive layer electrically connected to the second source line SL2 and insulating spacers surrounding sidewalls of the conductive layer.

The second bit line BL2 may be located under the second gate structure GST2. The second source line SL2 may be located over the second gate structure GST2. The second channel structure CH2 may extend through the second gate structure GST2 and may be connected between the second bit line BL2 and the second source line SL2. A second source select transistor SST2, a second memory cell MC2, or a second drain select transistor DST2 may be located in regions where the second channel structure CH2 and the second conductive layers 13 intersect each other. The second source select transistor SST2, the second memory cell MC2, and the second drain select transistor DST2 sharing the second channel structure CH2 with each other may constitute a second memory string MS2.

The first and second slit structures SLS1, SLS2 may be tapered with their cross-sectional areas decreasing as a distance from the substrate 10 increases. Likewise, the first and second channel structures CH1, CH2 may be tapered with their cross-sectional areas decreasing as a distance from the substrate 10 increases.

A first interconnection structure IC1 may include a first through via TV1. The first through via TV1 may extend through the first memory cell array CA1 and may pass through the first source line SL1 and the first gate structure GST1. The first through via TV1 may serve to connect the first bit line BL1 and the second bit line BL2 to each other. The first through via TV1 may also serve to connect the first memory string MS1 and the second memory string MS2 to each other.

The page buffer PB may be commonly connected to the first memory string MS1 and the second memory string MS2 through the first interconnection structure IC1. As an example, the first interconnection structure IC1 may include the via V01, the wiring line M01, the first bonding pad BP11, the first bit line BL1, a first via V11, the first through via TV1, the second bonding pad BP21, the second bit line BL2, and a second via V21.

A second interconnection structure IC2 may include a second through via TV2. The second through via TV2 may extend through the first memory cell array CA1 and may pass through the first gate structure GST1. The first word line WL1 and the second word line WL2 may be connected to each other through the second through via TV2. The second through via TV2 may be commonly connected to the first word line WL1 and the second word line WL2 corresponding to each other. As an example, the first word line WL1 located at an n-th layer in the first gate structure GST1 and the second word line WL2 located at an n-th layer in the second gate structure GST2 may be connected to each other. Here, n may be an integer.

The row decoder DEC may commonly control the first word line WL1 and the second word line WL2 through the second interconnection structure IC2. As an example, the second interconnection structure IC2 may include the via V02, the wiring line M02, the first bonding pad BP12, a first wiring line M12, a first via V12, the second through via TV2, the second bonding pad BP22, a second wiring line M22, and a second via V22.

A third interconnection structure IC3 may include the first and second slit structures SLS1 and SLS2. The source control circuit SRC may be commonly connected to the first source line SL1 and the second source line SL2 through the third interconnection structure IC3. As an example, the third interconnection structure IC3 may include the via V03, the wiring line M03, the first bonding pad BP13, a first wiring line M13, a first via V13, the first slit structure SLS1, the first source line SL1, the second bonding pad BP23, a second wiring line M23, a second via V23, the second slit structure SLS2, and the second source line SL2.

Referring to FIG. 1C, the third interconnection structure IC3 may include a third through via TV3 and a fourth through via TV4. The third through via TV3 may extend through the first memory cell array CA1, and may pass through the dummy region of the first gate structure GST1. The fourth through via TV4 may extend through the second memory cell array CA2 and may pass through the dummy region of the second gate structure GST2.

The source control circuit SRC may be commonly connected to the first source line SL1 and the second source line SL2 through the third interconnection structure IC3. As an example, the third interconnection structure IC3 may include the via V03, the wiring line M03, the first bonding pad BP13, a first wiring line M13, a first via V13, the third through via TV3, the second bonding pad BP23, a second wiring line M23, a second via V23, the fourth through via TV4, a third via V3, a third wiring line M3, the second source line SL2, the second slit structure SLS2, a second bonding via V24, a second wiring line M24, a second bonding pad BP24, and the first source line SL1.

According to the configuration described above, the first and second memory strings MS1, MS2 may be commonly connected to the page buffer PB, and the page buffer PB may selectively access the first memory string MS1 or the second memory string MS2. The first word lines WL1 and the second word lines WL2 may be commonly connected to the row decoder DEC, and the row decoder DEC may commonly control the first word lines WL1 and the second word lines WL2. The first source line SL1 and the second source line SL2 may be commonly connected to the source control circuit SRC, and the source control circuit SRC may commonly control the first source line SL1 and the second source line SL2. Accordingly, the first memory cell array CA1 and the second memory cell array CA2 may share the peripheral circuit PC with each other, and an area occupied by the peripheral circuit PC may be reduced.

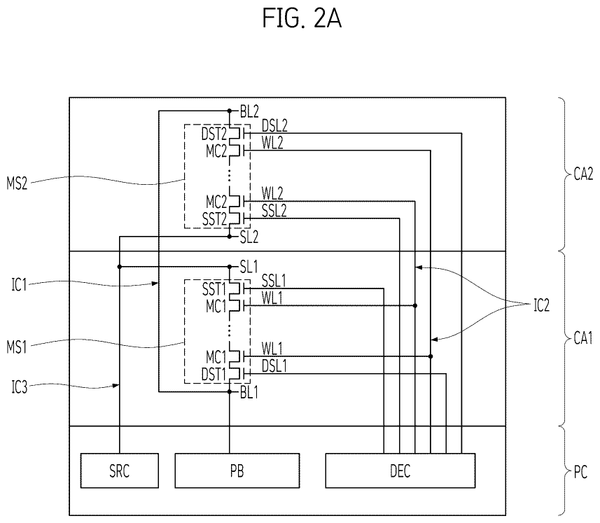

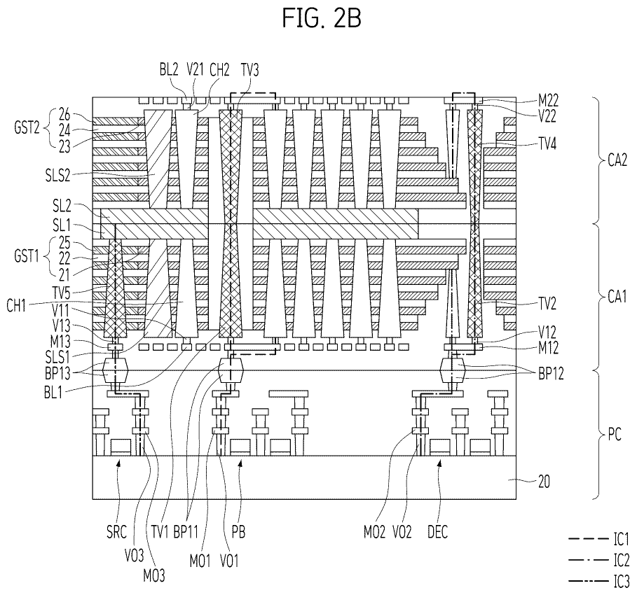

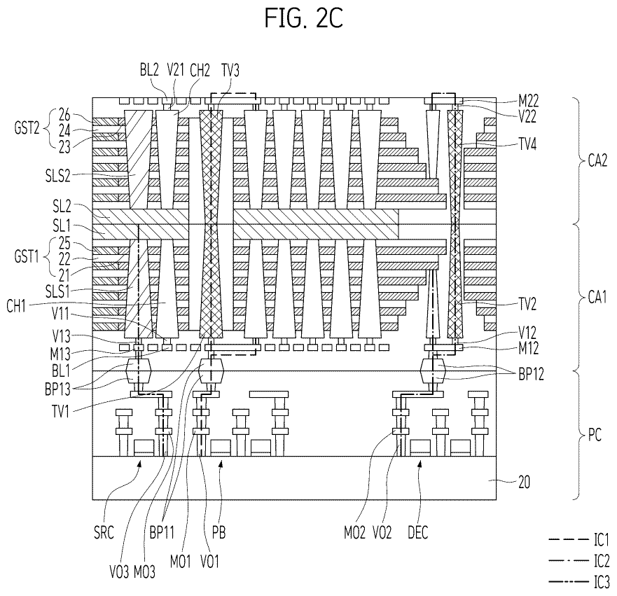

FIGS. 2A to 2C are diagrams illustrating a configuration of a semiconductor device in accordance with an embodiment of the present invention. Hereinafter, any content overlapping with previously described content may be omitted.

Referring to FIGS. 2A and 2B, the semiconductor device may include a peripheral circuit PC, a first memory cell array CA1 disposed over the peripheral circuit PC, and a second memory cell array CA2 disposed over the first memory cell array CA1. The peripheral circuit PC and the first memory cell array CA1 may be electrically connected to each other through bonding pads BP11, BP12, and BP13. The first memory cell array CA1 and the second memory cell array CA2 may be electrically and physically directly connected to each other without bonding pads.

The peripheral circuit PC may include a page buffer PB, a row decoder DEC, and a source control circuit SRC. As an example, the peripheral circuit PC may include a substrate 20 and at least one transistor located on the substrate 20. Vias V01, V02, and V03 and wiring lines M01, M02, and M03 may be connected to the peripheral circuit PC.

The first memory cell array CA1 may include a first gate structure GST1, a first channel structure CH1, a first bit line BL1, a first source line SL1, and a first slit structure SLS1. The first gate structure GST1 may include first conductive layers 21 and first insulating layers 22 that are alternately stacked. The first gate structure GST1 may include a dummy region. The dummy region may include first sacrificial layers 25 instead of the first conductive layers 21. The first slit structure SLS1 may extend through the first gate structure GST1, and may be connected to the first source line SL1.

The first bit line BL1 may be located under the first gate structure GST1. The first source line SL1 may be located over the first gate structure GST1. The first channel structure CH1 may extend through the first gate structure GST1 and may be connected between the first bit line BL1 and the first source line SL1.

The second memory cell array CA2 may include a second gate structure GST2, a second channel structure CH2, a second bit line BL2, a second source line SL2, and a second slit structure SLS2. The second gate structure GST2 may include second conductive layers 23 and second insulating layers 24 that are alternately stacked. The second gate structure GST2 may include a dummy region. The dummy region may include second sacrificial layers 26 instead of the second conductive layers 23. The second slit structure SLS2 may extend through the second gate structure GST2 and may be connected to the second source line SL2.

The second bit line BL2 may be located over the second gate structure GST2. The second source line SL2 may be located under the second gate structure GST2 and may be directly connected to the first source line SL1. The second channel structure CH2 may extend through the second gate structure GST2 and may be connected between the second bit line BL2 and the second source line SL2.

A first interconnection structure IC1 may include a first through via TV1 and a third through via TV3. The first through via TV1 may extend through the first memory cell array CA1 and may pass through the first source line SL1 and the first gate structure GST1. The third through via TV3 may extend through the second memory cell array CA2 and may pass through the second source line SL2 and the second gate structure GST2.

The first through via TV1 and the third through via TV3 may be directly connected to each other. The first through via TV1 may connect the first bit line BL1 and the third through via TV3 to each other, and the third through via TV3 may connect the first through via TV1 and the second bit line BL2 to each other. Through the first through via TV1 and the third through via TV3, the first bit line BL1 and the second bit line BL2 may be connected to each other, and a first memory string MS1 and a second memory string MS2 may be connected to each other.

The page buffer PB may be commonly connected to the first memory string MS1 and the second memory string MS2 through the first interconnection structure IC1. As an example, the first interconnection structure IC1 may include the via V01, the wiring line M01, the bonding pad BP11, the first bit line BL1, a first via V11, the first through via TV1, the third through via TV3, a second via V21, and the second bit line BL2.

A second interconnection structure IC2 may include a second through via TV2 and a fourth through via TV4. The second through via TV2 may extend through the first memory cell array CA1 and may pass through the first gate structure GST1. The fourth through via TV4 may extend through the second memory cell array CA2 and may pass through the second gate structure GST2.

The second through via TV2 and the fourth through via TV4 may be directly connected to each other. The second through via TV2 may connect a first word line WL1 and the fourth through via TV4 to each other, and the fourth through via TV4 may connect the second through via TV2 and a second word line WL2 to each other. The first word line WL1 and the second word line WL2 may be connected to each other through the second through via TV2 and the fourth through via TV4. The first word line WL1 located at an n-th layer in the first gate structure GST1 and the second word line WL2 located at an n-th layer in the second gate structure GST2 may be connected to each other.

The row decoder DEC may commonly control the first word lines WL1 and the second word lines WL2 through the second interconnection structure IC2. As an example, the second interconnection structure IC2 may include the via V02, the wiring line M02, the bonding pad BP12, a first wiring line M12, a first via V12, the second through via TV2, the fourth through via TV4, a second wiring line M22, and a second via V22.

A third interconnection structure IC3 may include a fifth through via TV5. The fifth through via TV5 may extend through the first memory cell array CA1 and may pass through the dummy region of the first gate structure GST1.

The source control circuit SRC may be commonly connected to the first source line SL1 and the second source line SL2 through the third interconnection structure IC3. As an example, the third interconnection structure IC3 may include the via V03, the wiring line M03, the bonding pad BP13, a first wiring line M13, a first via V13, the fifth through via TV5, the first source line SL1, and the second source line SL2.

Referring to FIGS. 2A and 2C, the third interconnection structure IC3 may include the first slit structure SLS1. As an example, the third interconnection structure IC3 may include the via V03, the wiring line M03, the bonding pad BP13, the first wiring line M13, the first via V13, the first slit structure SLS1, the first source line SL1, and the second source line SL2.

According to the configuration described above, the first memory string MS1 and the second memory string MS2 may be commonly connected to the page buffer PB, and the page buffer PB may selectively access the first memory string MS1 or the second memory string MS2. The first word lines WL1 and the second word lines WL2 may be commonly connected to the row decoder DEC, and the row decoder DEC may commonly control the first word lines WL1 and the second word lines WL2. The first source line SL1 and the second source line SL2 may be commonly connected to the source control circuit SRC, and the source control circuit SRC may commonly control the first source line SL1 and the second source line SL2. Accordingly, the first memory cell array CA1 and the second memory cell array CA2 may share the peripheral circuit PC with each other, and an area occupied by the peripheral circuit PC may be reduced.

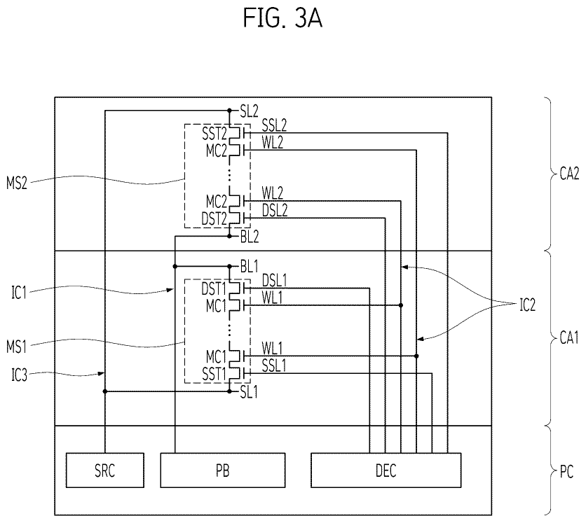

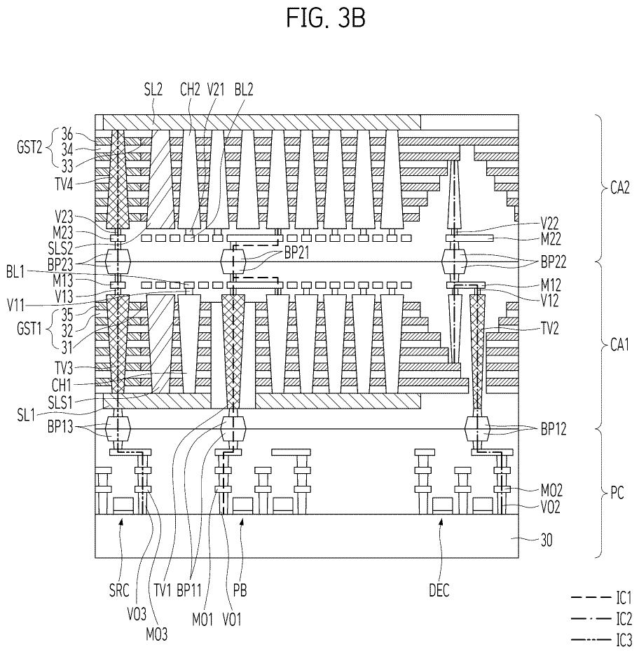

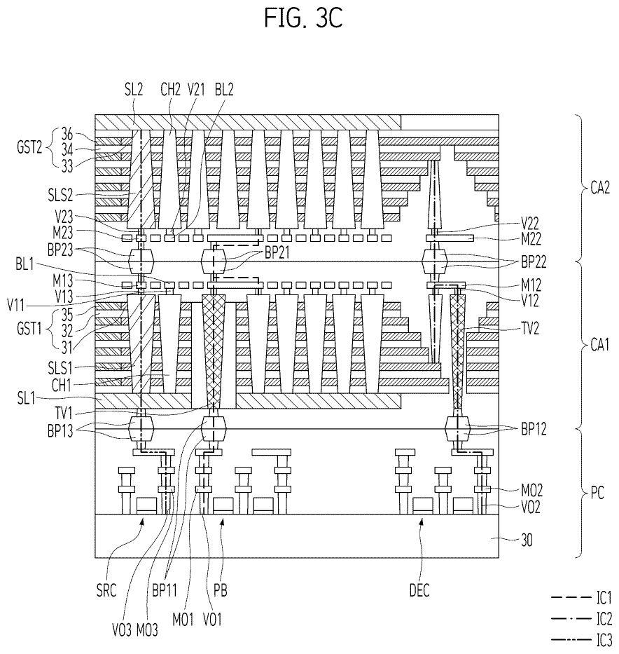

FIGS. 3A to 3C are diagrams illustrating a configuration of a semiconductor device in accordance with an embodiment of the present invention. Hereinafter, any content overlapping with previously described content may be omitted.

Referring to FIGS. 3A and 3B, the semiconductor device may include a peripheral circuit PC, a first memory cell array CA1 disposed over the peripheral circuit PC, and a second memory cell array CA2 disposed over the first memory cell array CA1. The peripheral circuit PC and the first memory cell array CA1 may be electrically connected to each other through first bonding pads BP11, BP12, and BP13. The first memory cell array CA1 and the second memory cell array CA2 may be electrically connected to each other through second bonding pads BP21, BP22, and BP23.

The peripheral circuit PC may include a page buffer PB, a row decoder DEC, and a source control circuit SRC. As an example, the peripheral circuit PC may include a substrate 30 and at least one transistor located on the substrate 30. Vias V01, V02, and V03 and wiring lines M01, M02, and M03 may be connected to the peripheral circuit PC.

The first memory cell array CA1 may include a first gate structure GST1, a first channel structure CH1, a first bit line BL1, a first source line SL1, and a first slit structure SLS1. The first gate structure GST1 may include first conductive layers 31 and first insulating layers 32 that are alternately stacked. The first gate structure GST1 may include a dummy region. The dummy region may include first sacrificial layers 35 instead of the first conductive layers 31. The first slit structure SLS1 may extend through the first gate structure GST1 and may be connected to the first source line SL1.

The first bit line BL1 may be located over the first gate structure GST1. The first source line SL1 may be located under the first gate structure GST1. The first channel structure CH1 may extend through the first gate structure GST1 and may be connected between the first bit line BL1 and the first source line SL1.

The second memory cell array CA2 may include a second gate structure GST2, a second channel structure CH2, a second bit line BL2, a second source line SL2, and a second slit structure SLS2. The second gate structure GST2 may include second conductive layers 33 and second insulating layers 34 that are alternately stacked. The second gate structure GST2 may include a dummy region. The dummy region may include second sacrificial layers 36 instead of the second conductive layers 33. The second slit structure SLS2 may extend through the second gate structure GST2 and may be connected to the second source line SL2.

The second bit line BL2 may be located under the second gate structure GST2. The second source line SL2 may be located over the second gate structure GST2. The second channel structure CH2 may extend through the second gate structure GST2 and may be connected between the second bit line BL2 and the second source line SL2.

A first interconnection structure IC1 may include a first through via TV1. The first through via TV1 may extend through the first memory cell array CA1 and may pass through the first source line SL1 and the first gate structure GST1. The first bit line BL1 and the first bonding pad BP11 may be connected to each other through the first through via TV1. The first interconnection structure IC1 may include the second bonding pad BP21 and may connect the first bit line BL1 and the second bit line BL2 to each other through the second bonding pad BP21. The page buffer PB may be commonly connected to a first memory string MS1 and a second memory string MS2 through the first interconnection structure IC1. As an example, the first interconnection structure IC1 may include the via V01, the wiring line M01, the first bonding pad BP11, the first through via TV1, a first via V11, the first bit line BL1, the second bonding pad BP21, the second bit line BL2, and a second via V21.

A second interconnection structure IC2 may include a second through via TV2. The second through via TV2 may extend through the first memory cell array CA1 and may pass through the first gate structure GST1. The second through via TV2 may be connected to a first word line WL1 and a second word line WL2. The first word line WL1 and the first bonding pad BP12 may be connected to each other through the second through via TV2. The second interconnection structure IC2 may include the second bonding pad BP22 and may connect the first word line WL1 and the second word line WL2 to each other through the second bonding pad BP22. The first word line WL1 located at an n-th layer in the first gate structure GST1 and the second word line WL2 located at an n-th layer in the second gate structure GST2 may be connected to each other. The row decoder DEC may commonly control the first word lines WL1 and the second word lines WL2 through the second interconnection structure IC2. As an example, the second interconnection structure IC2 may include the via V02, the wiring line M02, the first bonding pad BP12, the second through via TV2, a first via V12, a first wiring line M12, the second bonding pad BP22, a second wiring line M22, and a second via V22.

A third interconnection structure IC3 may include a third through via TV3 and a fourth through via TV4. The third through via TV3 may extend through the first memory cell array CA1 and may pass through the dummy region of the first gate structure GST1. The fourth through via TV4 may extend through the second memory cell array CA2 and may pass through the dummy region of the second gate structure GST2.

The source control circuit SRC may be commonly connected to the first source line SL1 and the second source line SL2 through the third interconnection structure IC3. As an example, the third interconnection structure IC3 may include the via V03, the wiring line M03, the first bonding pad BP13, the first source line SL1, the third through via TV3, a first via V13, a first wiring line M13, the second bonding pad BP23, a second wiring line M23, a second via V23, the fourth through via TV4, and the second source line SL2.

Referring to FIGS. 3A and 3C, the third interconnection structure IC3 may include the first slit structure SLS1 and the second slit structure SLS2. As an example, the third interconnection structure IC3 may include the via V03, the wiring line M03, the first bonding pad BP13, the first source line SL1, the first slit structure SLS1, a first via V13, a first wiring line M13, the second bonding pad BP23, a second wiring line M23, a second via V23, the second slit structure SLS2, and the second source line SL2.

According to the configuration described above, the first memory string MS1 and the second memory string MS2 may be commonly connected to the page buffer PB, and the page buffer PB may selectively access the first memory string MS1 or the second memory string MS2. The first word lines WL1 and the second word lines WL2 may be commonly connected to the row decoder DEC, and the row decoder DEC may commonly control the first word lines WL1 and the second word lines WL2. The first source line SL1 and the second source line SL2 may be commonly connected to the source control circuit SRC, and the source control circuit SRC may commonly control the first source line SL1 and the second source line SL2. Accordingly, the first memory cell array CA1 and the second memory cell array CA2 may share the peripheral circuit PC with each other, and an area occupied by the peripheral circuit PC may be reduced.

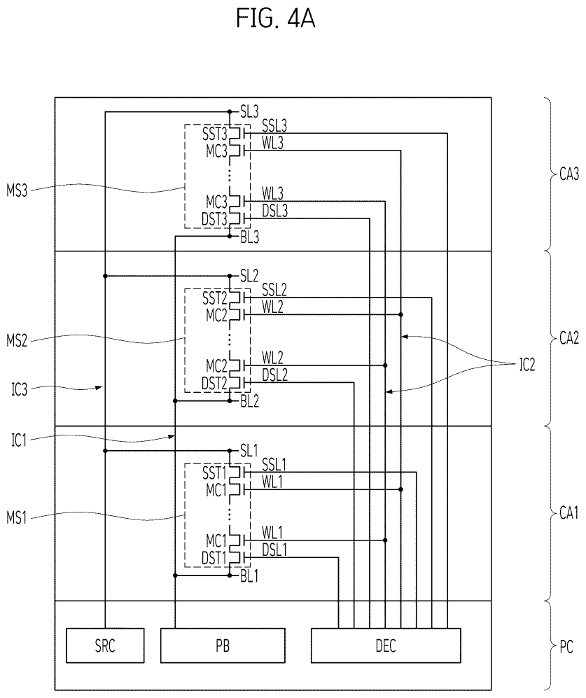

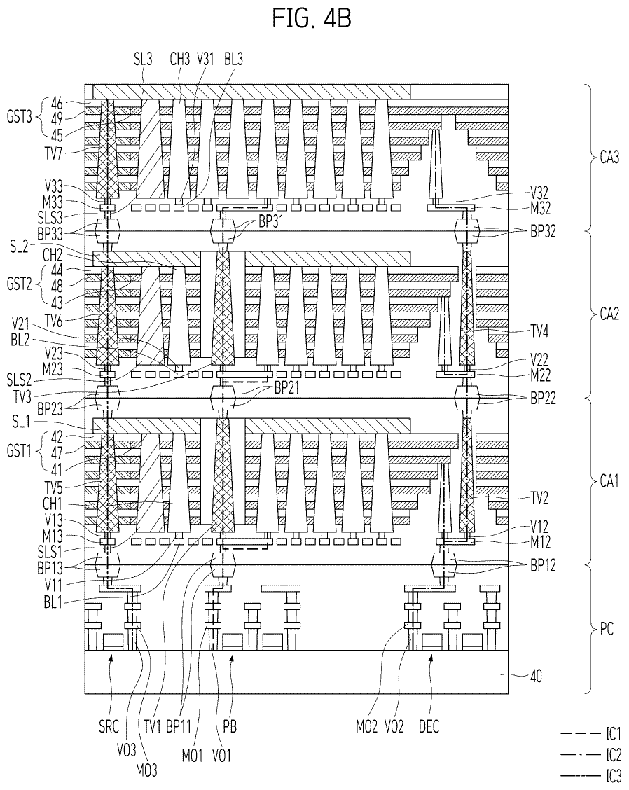

FIGS. 4A and 4B are diagrams illustrating a configuration of a semiconductor device in accordance with an embodiment of the present invention. Hereinafter, any content overlapping with previously described content may be omitted.

Referring to FIGS. 4A and 4B, the semiconductor device may include a peripheral circuit PC, a first memory cell array CA1, a second memory cell array CA2, and a third memory cell array CA3. The first memory cell array CA1, the second memory cell array CA2, and the third memory cell array CA3 may be stacked over the peripheral circuit PC. The peripheral circuit PC and the first memory cell array CA1 may be electrically connected to each other through first bonding pads BP11, BP12, and BP13. The first memory cell array CA1 and the second memory cell array CA2 may be electrically connected to each other through second bonding pads BP21, BP22, and BP23. The second memory cell array CA2 and the third memory cell array CA3 may be electrically connected to each other through third bonding pads BP31, BP32, and BP33.

The peripheral circuit PC may include a page buffer PB, a row decoder DEC, and a source control circuit SRC. As an example, the peripheral circuit PC may include a substrate 40 and at least one transistor located on the substrate 40. Vias V01, V02, and V03 and wiring lines M01, M02, and M03 may be connected to the peripheral circuit PC.

The first memory cell array CA1 may include a first gate structure GST1, a first channel structure CH1, a first bit line BL1, a first source line SL1, and a first slit structure SLS1. The first gate structure GST1 may include first conductive layers 41 and first insulating layers 42 that are alternately stacked. The first gate structure GST1 may include a dummy region. The dummy region may include first sacrificial layers 47 instead of the first conductive layers 41. The first slit structure SLS1 may extend through the first gate structure GST1, and may be connected to the first source line SL1.

The first bit line BL1 may be located under the first gate structure GST1. The first source line SL1 may be located over the first gate structure GST1. The first channel structure CH1 may extend through the first gate structure GST1, and may be connected between the first bit line BL1 and the first source line SL1.

The second memory cell array CA2 may include a second gate structure GST2, a second channel structure CH2, a second bit line BL2, a second source line SL2, and a second slit structure SLS2. The second gate structure GST2 may include second conductive layers 43 and second insulating layers 44 that are alternately stacked. The second gate structure GST2 may include a dummy region. The dummy region may include second sacrificial layers 48 instead of the second conductive layers 43. The second slit structure SLS2 may extend through the second gate structure GST2 and may be connected to the second source line SL2.

The second bit line BL2 may be located under the second gate structure GST2. The second source line SL2 may be located over the second gate structure GST2. The second channel structure CH2 may extend through the second gate structure GST2 and may be connected between the second bit line BL2 and the second source line SL2.

The third memory cell array CA3 may include a third gate structure GST3, a third channel structure CH3, a third bit line BL3, a third source line SL3, and a third slit structure SLS3. The third gate structure GST3 may include third conductive layers 45 and third insulating layers 46 that are alternately stacked. The third gate structure GST3 may include a dummy region. The dummy region may include third sacrificial layers 49 instead of the third conductive layers 45. The third slit structure SLS3 may extend through the third gate structure GST3 and may be connected to the third source line SL3.

The third bit line BL3 may be located under the third gate structure GST3. The third source line SL3 may be located over the third gate structure GST3. The third channel structure CH3 may extend through the third gate structure GST3 and may be connected between the third bit line BL3 and the third source line SL3.

A first interconnection structure IC1 may include a first through via TV1. The first through via TV1 may extend through the first memory cell array CA1 and may pass through the first source line SL1 and the first gate structure GST1. Through the first through via TV1, the first bit line BL1 and the second bit line BL2 may be connected to each other, and a first memory string MS1 and a second memory string MS2 may be connected to each other.

The first interconnection structure IC1 may include a third through via TV3. The third through via TV3 may extend through the second memory cell array CA2 and may pass through the second source line SL2 and the second gate structure GST2. Through the third through via TV3, the second bit line BL2 and the third bit line BL3 may be connected to each other, and the second memory string MS2 and a third memory string MS3 may be connected to each other.

The page buffer PB may be commonly connected to the first memory string MS1, the second memory string MS2, and the third memory string MS3 through the first interconnection structure IC1. As an example, the first interconnection structure IC1 may include the via V01, the wiring line M01, the first bonding pad BP11, the first bit line BL1, a first via V11, the first through via TV1, the second bonding pad BP21, the second bit line BL2, a second via V21, the third through via TV3, the third bonding pad BP31, the third bit line BL3, and a third via V31.

A second interconnection structure IC2 may include a second through via TV2. The second through via TV2 may extend through the first memory cell array CA1 and may pass through the first gate structure GST1. First word lines WL1 and second word lines WL2 may be connected to each other through the second through via TV2. The first word line WL1 located at an n-th layer in the first gate structure GST1 and the second word line WL2 located at an n-th layer in the second gate structure GST2 may be connected to each other.

The second interconnection structure IC2 may include a fourth through via TV4. The fourth through via TV4 may extend through the second memory cell array CA2 and may pass through the second gate structure GST2. The second word lines WL2 and third word lines WL3 may be connected to each other through the fourth through via TV4. The second word line WL2 located at an n-th layer in the second gate structure GST2 and the third word line WL3 located at an n-th layer in the third gate structure GST3 may be connected to each other.

The row decoder DEC may commonly control the first word lines WL1, the second word lines WL2, and the third word lines WL3 through the second interconnection structure IC2. As an example, the second interconnection structure IC2 may include the via V02, the wiring line M02, the first bonding pad BP12, a first wiring line M12, a first via V12, the second through via TV2, the second bonding pad BP22, a second wiring line M22, a second via V22, the fourth through via TV4, the third bonding pad BP32, a third wiring line M32, and a third a via V32.

A third interconnection structure IC3 may include a fifth through via TV5, a sixth through via TV6, and a seventh through via TV7. The fifth through via TV5 may extend through the first memory cell array CA1 and may pass through the dummy region of the first gate structure GST1. The sixth through via TV6 may extend through the second memory cell array CA2 and may pass through the dummy region of the second gate structure GST2. The seventh through via TV7 may extend through the third memory cell array CA3 and may pass through the dummy region of the third gate structure GST3.

The source control circuit SRC may be commonly connected to the first source line SL1, the second source line SL2, and the third source line SL3 through the third interconnection structure IC3. As an example, the third interconnection structure IC3 may include the via V03, the wiring line M03, the first bonding pad BP13, a first wiring line M13, a first via V13, the fifth through via TV5, the first source line SL1, the second bonding pad BP23, a second wiring line M23, a second via V23, the sixth through via TV6, the second source line SL2, the third bonding pad BP33, a third wiring line M33, a third via V33, the seventh through via TV7, and the third source line SL3.

According to the configuration described above, the first memory string MS1, the second memory string MS2, and the third memory string MS3 may be commonly connected to the page buffer PB, and the page buffer PB may selectively access the first memory string MS1, the second memory string MS2, or the third memory string MS3. The first word lines WL1, the second word lines WL2, and the third word lines WL3 may be commonly connected to the row decoder DEC, and the row decoder DEC may commonly control the first word lines WL1, the second word lines WL2, and the third word lines WL3. The first source line SL1, the second source line SL2, and the third source line SL3 may be commonly connected to the source control circuit SRC, and the source control circuit SRC may commonly control the first source line SL1, the second source line SL2, and the third source line SL3. Accordingly, the first memory cell array CA1, the second memory cell array CA2, and the third memory cell array CA3 may share the peripheral circuit PC with each other, and an area occupied by the peripheral circuit PC may be reduced.

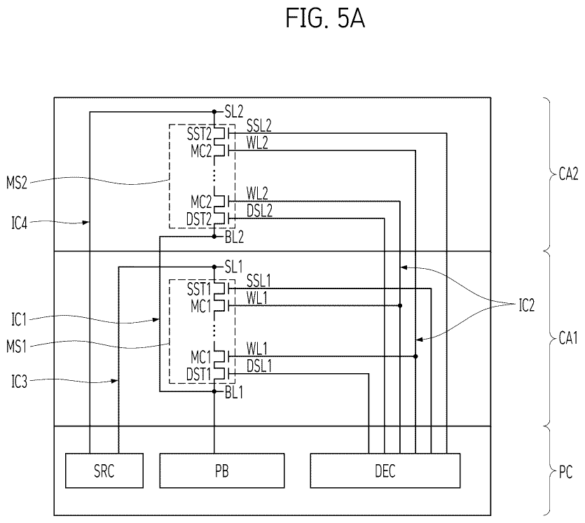

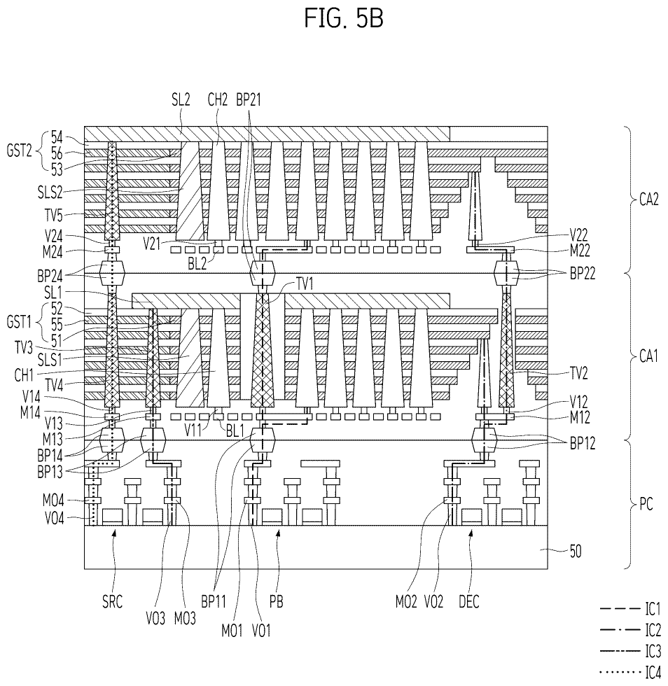

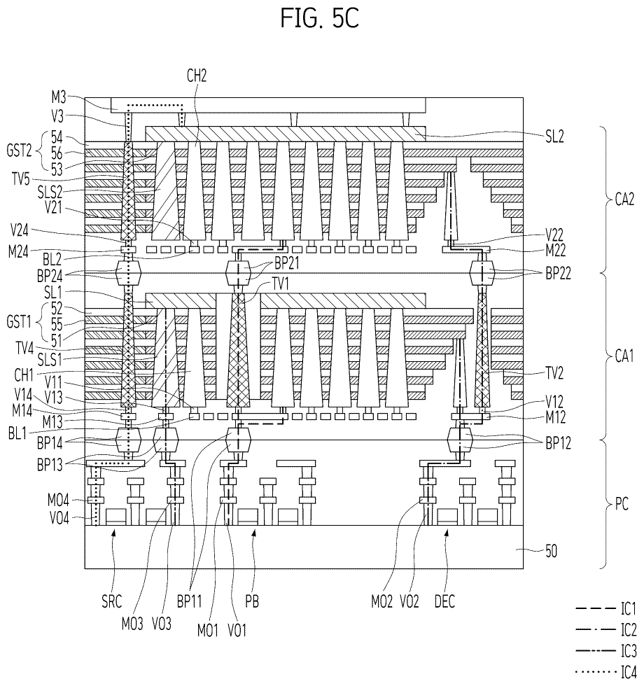

FIGS. 5A to 5C are simplified diagrams of a structure of a semiconductor device in accordance with an embodiment of the present invention. Hereinafter, any content overlapping with previously described content may be omitted.

Referring to FIGS. 5A and 5B, the semiconductor device may include a peripheral circuit PC, a first memory cell array CA1 disposed over the peripheral circuit PC, and a second memory cell array CA2 disposed over the first memory cell array CA1. The peripheral circuit PC and the first memory cell array CA1 may be electrically connected to each other through first bonding pads BP11, BP12, BP13, and BP14. The first memory cell array CA1 and the second memory cell array CA2 may be electrically connected to each other through second bonding pads BP21, BP22, and BP24.

The peripheral circuit PC may include a page buffer PB, a row decoder DEC, and a source control circuit SRC. As an example, the peripheral circuit PC may include a substrate 50 and at least one transistor located on the substrate 50. Vias V01, V02, V03, and V04 and wiring lines M01, M02, M03, and M04 may be connected to the peripheral circuit PC.

The first memory cell array CA1 may include a first gate structure GST1, a first channel structure CH1, a first bit line BL1, a first source line SL1, and a first slit structure SLS1. The first gate structure GST1 may include first conductive layers 51 and first insulating layers 52 that are alternately stacked. The first gate structure GST1 may include a dummy region. The dummy region may include first sacrificial layers 55 instead of the first conductive layers 51. The first slit structure SLS1 may extend through the first gate structure GST1 and may be connected to the first source line SL1.

The first bit line BL1 may be located under the first gate structure GST1. The first source line SL1 may be located over the first gate structure GST1. The first channel structure CH1 may extend through the first gate structure GST1 and may be connected between the first bit line BL1 and the first source line SL1.

The second memory cell array CA2 may include a second gate structure GST2, a second channel structure CH2, a second bit line BL2, a second source line SL2, and a second slit structure SLS2. The second gate structure GST2 may include second conductive layers 53 and second insulating layers 54 that are alternately stacked. The second gate structure GST2 may include a dummy region. The dummy region may include second sacrificial layers 56 instead of the second conductive layers 53. The second slit structure SLS2 may extend through the second gate structure GST2 and may be connected to the second source line SL2.

The second bit line BL2 may be located under the second gate structure GST2. The second source line SL2 may be located over the second gate structure GST2. The second channel structure CH2 may extend through the second gate structure GST2 and may be connected between the second bit line BL2 and the second source line SL2.

A first interconnection structure IC1 may include a first through via TV1, and the page buffer PB may be commonly connected to a first memory string MS1 and a second memory string MS2 through the first interconnection structure IC1.

A second interconnection structure IC2 may include a second through via TV2, and the row decoder DEC may commonly control a first word line WL1 and a second word line WL2 through the second interconnection structure IC2.

A third interconnection structure IC3 may include a third through via TV3. The third through via TV3 may pass through the dummy region of the first gate structure GST1 and may be connected to the first source line SL1. The source control circuit SRC may control the first source line SL1 through the third interconnection structure IC3. As an example, the third interconnection structure IC3 may include the via V03, the wiring line M03, the first bonding pad BP13, a first wiring line M13, a first via V13, the third through via TV3, and the first source line SL1.

A fourth interconnection structure IC4 may include a fourth through via TV4 and a fifth through via TV5. The fourth through via TV4 may pass through the dummy region of the first gate structure GST1, and the fifth through via TV5 may pass through the dummy region of the second gate structure GST2. The source control circuit SRC may control the second source line SL2 through the fourth interconnection structure IC4. As an example, the fourth interconnection structure IC4 may include the via V04, the wiring line M04, the first bonding pad BP14, a first wiring line M14, a first via V14, the fourth through via TV4, the second bonding pad BP24, a second wiring line M24, a second via V24, the fifth through via TV5, and the second source line SL2.

Referring to FIGS. 5A and 5C, the third interconnection structure IC3 may include the first slit structure SLS1. The source control circuit SRC may control the first source line SL1 through the third interconnection structure IC3. As an example, the third interconnection structure IC3 may include the via V03, the wiring line M03, the first bonding pad BP13, a first wiring line M13, a first via V13, the first slit structure SLS1, and the first source line SL1.

The fourth interconnection structure IC4 may include a fourth through via TV4 and a fifth through via TV5. The fourth through via TV4 may pass through the dummy region of the first gate structure GST1, and the fifth through via TV5 may pass through the dummy region of the second gate structure GST2. The source control circuit SRC may control the second source line SL2 through the fourth interconnection structure IC4. As an example, the fourth interconnection structure IC4 may include the via V04, the wiring line M04, the first bonding pad BP14, a first wiring line M14, a first via V14, the fourth through via TV4, the second bonding pad BP24, a second wiring line M24, a second via V24, the fifth through via TV5, a third via V3, a third wiring line M3, and the second source line SL2.

According to the configuration described above, the first source line SL1 and the second source line SL2 may be respectively connected to the source control circuit SRC, and the source control circuit SRC may individually control the first source line SL1 and the second source line SL2. Accordingly, a memory block may be divided into sub-memory block units, and an erase operation may be performed in sub-memory block units.

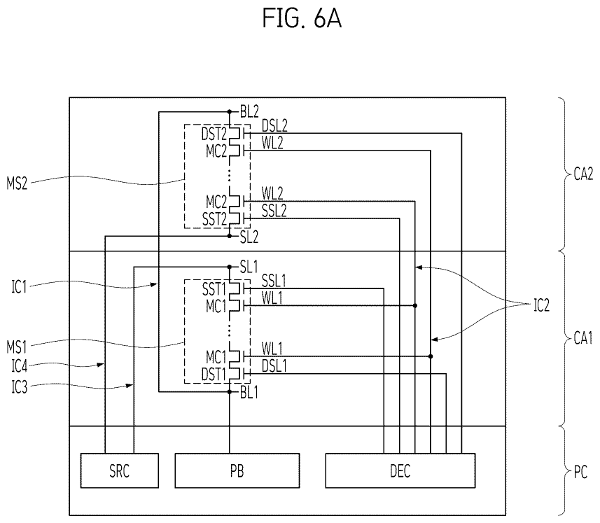

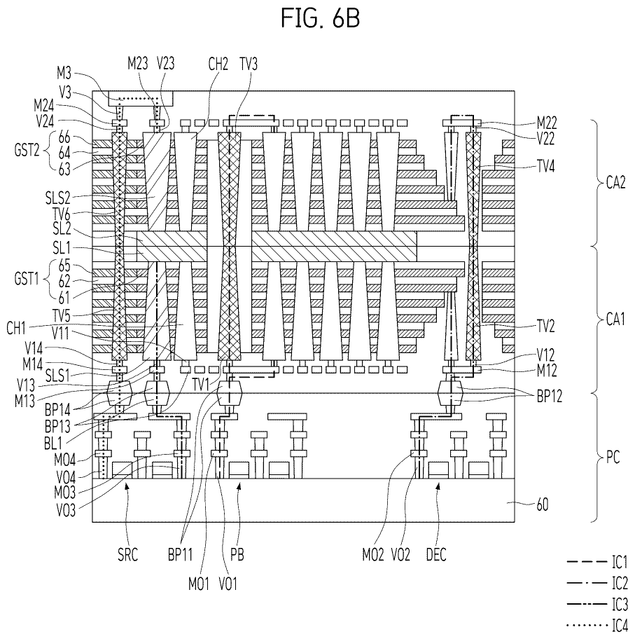

FIGS. 6A and 6B are simplified diagrams of a structure of a semiconductor device in accordance with an embodiment of the present invention. Hereinafter, any content overlapping with previously described content may be omitted.

Referring to FIGS. 6A and 6B, the semiconductor device may include a peripheral circuit PC, a first memory cell array CA1 disposed over the peripheral circuit PC, and a second memory cell array CA2 disposed over the first memory cell array CA1. The peripheral circuit PC and the first memory cell array CA1 may be electrically connected to each other through first bonding pads BP11, BP12, BP13, and BP14. The first memory cell array CA1 and the second memory cell array CA2 may be connected electrically to each other using through vias TV1, TV2, TV3, TV4, TV5 and TV6 without bonding pads.

The peripheral circuit PC may include a page buffer PB, a row decoder DEC, and a source control circuit SRC. As an example, the peripheral circuit PC may include a substrate 60 and at least one transistor located on the substrate 60. Vias V01, V02, V03, and V04 and wiring lines M01, M02, M03, and M04 may be connected to the peripheral circuit PC.

The first memory cell array CA1 may include a first gate structure GST1, a first channel structure CH1, a first bit line BL1, a first source line SL1, and a first slit structure SLS1. The first gate structure GST1 may include first conductive layers 61 and first insulating layers 62 that are alternately stacked. The first gate structure GST1 may include a dummy region. The dummy region may include first sacrificial layers 65 instead of the first conductive layers 61. The first slit structure SLS1 may extend through the first gate structure GST1 and may be connected to the first source line SL1.

The first bit line BL1 may be located under the first gate structure GST1. The first source line SL1 may be located over the first gate structure GST1. The first channel structure CH1 may extend through the first gate structure GST1 and may be connected between the first bit line BL1 and the first source line SL1.

The second memory cell array CA2 may include a second gate structure GST2, a second channel structure CH2, a second bit line BL2, a second source line SL2, and a second slit structure SLS2. The second gate structure GST2 may include second conductive layers 63 and second insulating layers 64 that are alternately stacked. The second gate structure GST2 may include a dummy region. The dummy region may include second sacrificial layers 66 instead of the second conductive layers 63. The second slit structure SLS2 may extend through the second gate structure GST2 and may be connected to the second source line SL2.

The second bit line BL2 may be located over the second gate structure GST2. The second source line SL2 may be located under the second gate structure GST2. The second channel structure CH2 may extend through the second gate structure GST2 and may be connected between the second bit line BL2 and the second source line SL2.

A first interconnection structure IC1 may include a first through via TV1 and a third through via TV3, and the page buffer PB may be commonly connected to a first memory string MS1 and a second memory string MS2 through the first interconnection structure IC1.

A second interconnection structure IC2 may include a second through via TV2 and a fourth through via TV4, and the row decoder DEC may commonly control a first word line WL1 and a second word line WL2 through the second interconnection structure IC2.

A third interconnection structure IC3 may include the first slit structure SLS1. The source control circuit SRC may control the first source line SL1 through the third interconnection structure IC3. As an example, the third interconnection structure IC3 may include the via V03, the wiring line M03, the first bonding pad BP13, a first wiring line M13, a first via V13, the first slit structure SLS1, and the first source line SL1.

A fourth interconnection structure IC4 may include a fifth through via TV5 and a sixth through via TV6. The fifth through via TV5 may pass through the dummy region of the first gate structure GST1, and the sixth through via TV6 may pass through the dummy region of the second gate structure GST2. The source control circuit SRC may control the second source line SL2 through the fourth interconnection structure IC4. As an example, the fourth interconnection structure IC4 may include the via V04, the wiring line M04, the first bonding pad BP14, a first wiring line M14, a first via V14, the fifth through via TV5, the sixth through via TV6, a second via V24, a second wiring line M24, a third via V3, a third wiring line M3, a second wiring line M23, a second via V23, the second slit structure SLS2, and the second source line SL2.

According to the configuration described above, the first source line SL1 and the second source line SL2 may be respectively connected to the source control circuit SRC, and the source control circuit SRC may individually control the first source line SL1 and the second source line SL2. Accordingly, a memory block may be divided into sub-memory block units, and an erase operation may be performed in sub-memory block units.

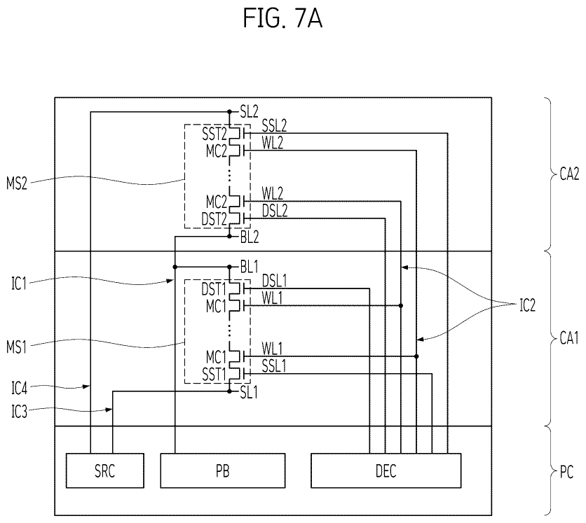

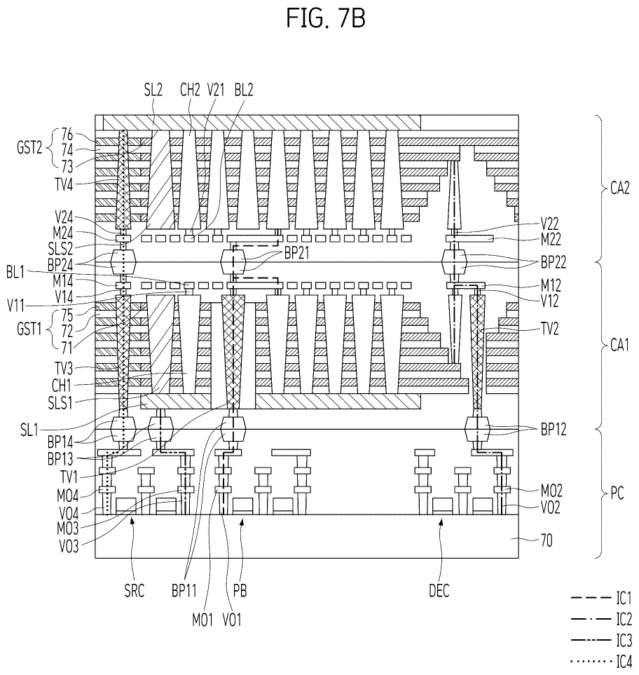

FIGS. 7A and 7B are simplified diagrams of a structure of a semiconductor device in accordance with an embodiment of the present invention. Hereinafter, any content overlapping with previously described content may be omitted.

Referring to FIGS. 7A and 7B, the semiconductor device may include a peripheral circuit PC, a first memory cell array CA1 disposed over the peripheral circuit PC, and a second memory cell array CA2 disposed over the first memory cell array CA1. The peripheral circuit PC and the first memory cell array CA1 may be electrically connected to each other through first bonding pads BP11, BP12, BP13, and BP14. The first memory cell array CA1 and the second memory cell array CA2 may be electrically connected to each other through second bonding pads BP21, BP22, and BP24.

The peripheral circuit PC may include a page buffer PB, a row decoder DEC, and a source control circuit SRC. As an example, the peripheral circuit PC may include a substrate 70 and at least one transistor located on the substrate 70. Vias V01, V02, V03, and V04 and wiring lines M01, M02, M03, and M04 may be connected to the peripheral circuit PC.

The first memory cell array CA1 may include a first gate structure GST1, a first channel structure CH1, a first bit line BL1, a first source line SL1, and a first slit structure SLS1. The first gate structure GST1 may include first conductive layers 71 and first insulating layers 72 that are alternately stacked. The first gate structure GST1 may include a dummy region. The dummy region may include first sacrificial layers 75 instead of the first conductive layers 71. The first slit structure SLS1 may extend through the first gate structure GST1 and may be connected to the first source line SL1.

The first bit line BL1 may be located over the first gate structure GST1, and the first source line SL1 may be located under the first gate structure GST1. The first channel structure CH1 may extend through the first gate structure GST1 and may be connected between the first bit line BL1 and the first source line SL1.

The second memory cell array CA2 may include a second gate structure GST2, a second channel structure CH2, a second bit line BL2, a second source line SL2, and a second slit structure SLS2. The second gate structure GST2 may include second conductive layers 73 and second insulating layers 74 that are alternately stacked. The second gate structure GST2 may include a dummy region. The dummy region may include second sacrificial layers 76 instead of the second conductive layers 73. The second slit structure SLS2 may extend through the second gate structure GST2 and may be connected to the second source line SL2.

The second bit line BL2 may be located under the second gate structure GST2 and the second source line SL2 may be located over the second gate structure GST2. The second channel structure CH2 may extend through the second gate structure GST2 and may be connected between the second bit line BL2 and the second source line SL2.

A first interconnection structure IC1 may include a first through via TV1, and the page buffer PB may be commonly connected to a first memory string MS1 and a second memory string MS2 through the first interconnection structure IC1.

A second interconnection structure IC2 may include a second through via TV2, and the row decoder DEC may commonly control a first word line WL1 and a second word line WL2 through the second interconnection structure IC2.

The source control circuit SRC may control the first source line SL1 through the third interconnection structure IC3. As an example, the third interconnection structure IC3 may include the via V03, the wiring line M03, the first bonding pad BP13, and the first source line SL1.

A fourth interconnection structure IC4 may include a third through via TV3 and a fourth through via TV4. The third through via TV3 may pass through the dummy region of the first gate structure GST1, and the fourth through via TV4 may pass through the dummy region of the second gate structure GST2. The source control circuit SRC may control the second source line SL2 through the fourth interconnection structure IC4. As an example, the fourth interconnection structure IC4 may include the via V04, the wiring line M04, the first bonding pad BP14, the third through via TV3, a first via V14, a first wiring line M14, the second bonding pad BP24, a second wiring line M24, a second via V24, the fourth through via TV4, and the second source line SL2.

According to the configuration described above, the first source line SL1 and the second source line SL2 may be respectively connected to the source control circuit SRC, and the source control circuit SRC may individually control the first source line SL1 and the second source line SL2. Accordingly, a memory block may be divided into sub-memory block units, and an erase operation may be performed in sub-memory block units.

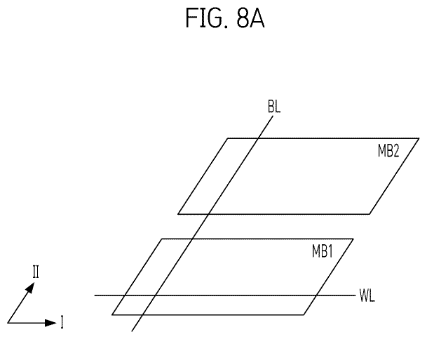

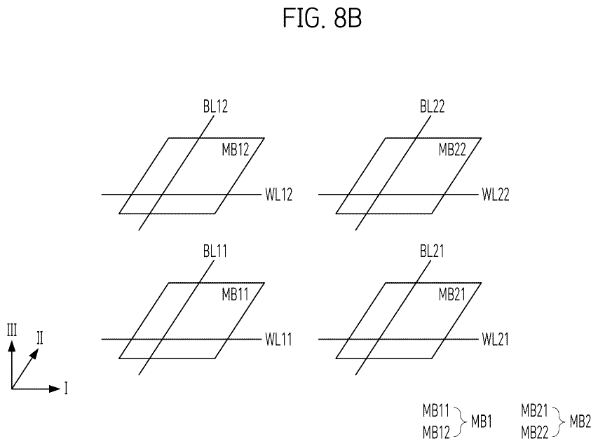

FIGS. 8A and 8B are diagrams illustrating a configuration of a semiconductor device in accordance with an embodiment of the present invention. Hereinafter, any content overlapping with previously described content may be omitted.

Referring to FIG. 8A, the semiconductor device may include a first memory block MB1 and a second memory block MB2. For example, as illustrated, the first memory block MB1 and the second memory block MB2 may be located on the same plane. In the first memory block MB1 and the second memory block MB2, a word line WL may extend in a first direction I, and a bit line BL may extend in a second direction II intersecting the first direction I. The first memory block MB1 and the second memory block MB2 may be adjacent to each other in the second direction II. In an embodiment, the first and second directions may be orthogonal to each other.

Referring to FIG. 8B, the semiconductor device may include a first memory block MB1 and a second memory block MB2. The first memory block MB1 may include a first sub-memory block MB11 and a second sub-memory block MB12. The second memory block MB2 may include a third sub-memory block MB21 and a fourth sub-memory block MB22.

The first sub-memory block MB11 and the second sub-memory block MB12 may be stacked in a third direction III. Here, the third direction III may be a direction perpendicular to a plane defined by the first direction I and the second direction II. A first word line WL11 of the first sub-memory block MB11 and a second word line WL21 of the second sub-memory block MB12 may be connected in common and may share a row decoder with each other. A first bit line BL11 of the first sub-memory block MB11 and a second bit line BL12 of the second sub-memory block MB12 may be connected in common and may share a page buffer with each other.

The third sub-memory block MB21 and the fourth sub-memory block MB22 may be stacked in the third direction III. A third word line WL21 of the third sub-memory block MB21 and a fourth word line WL22 of the fourth sub-memory block MB22 may be connected in common and may share a row decoder with each other. A third bit line BL21 of the third sub-memory block MB21 and a fourth bit line BL22 of the fourth sub-memory block MB22 may be connected in common and may share a page buffer with each other.

Comparing FIGS. 8A and 8B with each other, when a memory capacity of the semiconductor device illustrated in FIG. 8A and a memory capacity of the semiconductor device illustrated in FIG. 8B are the same as each other, a bit line length and/or a word line length of FIG. 8B may be smaller than a bit line length and/or a word line length of FIG. 8A. Through such a length reduction, it is possible to reduce bit line loading and/or word line loading.

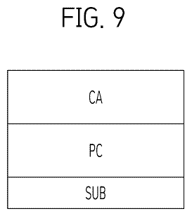

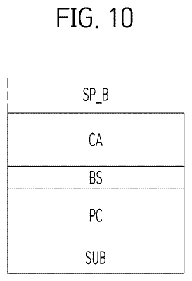

The structures and the manufacturing methods according to the above-described embodiments may be applied to semiconductor devices having various structures. FIGS. 9 and 10 illustrate schematic configurations of semiconductor devices to which the above-described embodiments are applicable.

FIG. 9 is a configuration diagram of a semiconductor device in accordance with an embodiment of the present invention.

Referring to FIG. 9, the semiconductor device may include a substrate SUB, a peripheral circuit PC, and a memory cell array CA. Here, the peripheral circuit PC and the memory cell array CA may be formed on the same substrate.

The substrate SUB may include a semiconductor material. As an example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method and may partially include metal. The substrate SUB may have a single crystalline, polycrystalline, or amorphous state. The substrate SUB may include group II, group III, group IV, group V, or group VI impurities. As an example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. As an example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operating voltage and may include a contact plug, a wiring line, and the like.

The memory cell array CA may include memory cells. As an example, the memory cell array CA may include memory strings connected between a source line and a bit line, and each memory string may include stacked memory cells. As an example, the memory cell array CA may include memory cells connected between a word line and the bit line. The memory cell array CA may further include an interconnection structure.

FIG. 10 is a configuration diagram of a semiconductor device in accordance with an embodiment of the present invention.

Referring to FIG. 10, the semiconductor device may include a substrate SUB, a peripheral circuit PC, a bonding structure BS, and a memory cell array CA. Here, the peripheral circuit PC and the memory cell array CA may be formed on separate substrates, respectively, and then bonded to each other. The semiconductor device may further include a support base SP_B.

The substrate SUB may be used as a support in a process of forming the peripheral circuit PC. The support base SP_B may be used as a support in a process of forming the memory cell array CA. As an example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. As an example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding layer, a bonding interface, and the like. The bonding pad may include metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be directly connected to each other without a bonding pad. As an example, a bonding layer included in the memory cell array CA and a bonding layer included in the peripheral circuit PC may be bonded to each other to form a bonding interface, and an interconnection structure included in the memory cell array CA and an interconnection structure included the peripheral circuit PC may be directly connected to each other. Through this, contact plugs, wiring lines, and the like, formed on different wafers may be electrically connected to each other without a separate bonding pad.

Other configurations may be the same as or similar to those described above with reference to FIG. 9.

It is also possible for the semiconductor device to have a structure in which embodiments described above with reference to FIGS. 9 and 10 are combined with each other or have a partially modified structure. In embodiments described with reference to FIGS. 9 and 10, locations of the memory cell array CA and the peripheral circuit PC may be changed. At least one memory cell array CA and/or at least one peripheral circuit PC may be additionally bonded in an embodiment described with reference to FIG. 9. As an example, a portion of the peripheral circuit PC may be located in the memory cell array CA.

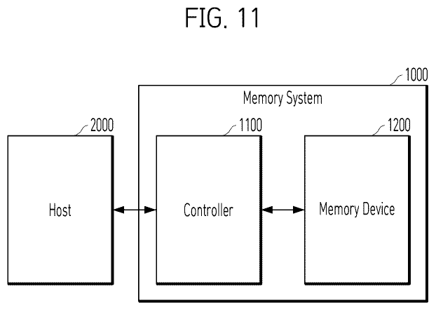

FIG. 11 is a simplified diagram of a memory system in accordance with an embodiment of the present invention.

Referring to FIG. 11, the memory system 1000 may include a memory device 1200 in which data is stored and a controller 1100 that communicates between the memory device 1200 and a host 2000.

The host 2000 may be a device or a system storing data in the memory system 1000 or retrieving data from the memory system 1000. The host 2000 may generate requests for various operations and output the generated requests to the memory system 1000. The requests may include a program request for a program operation, a read request for a read operation, an erase request for an erase operation, and the like. The host 2000 may communicate with the memory system 1000 through various interfaces such as peripheral component interconnect express (PCIe), advanced technology attachment (ATA), serial ATA (SATA), parallel ATA (PATA), serial attached SCSI (SAS), non-volatile memory express (NVMe), universal serial bus (USB), multi-media card (MMC), enhanced small disk interface (ESDI), and integrated drive electronics (IDE).

The host 2000 may include at least one of a computer, a portable digital device, a tablet personal computer (PC), a digital camera, a digital audio player, a television, a wireless communication device, or a cellular phone, but embodiments of the present disclosure are not limited thereto.

The controller 1100 may control an overall operation of the memory system 1000. The controller 1100 may control the memory device 1200 according to a request from the host 2000. The controller 1100 may control the memory device 1200 so that the program operation, the read operation, the erase operation, and the like, may be performed according to the request from the host 2000. Alternatively, the controller 1100 may perform a background operation for improving the performance characteristics of the memory system 1000 even without receiving a request from the host 2000.

The controller 1100 may transmit control signals and data signals to the memory device 1200 for controlling an operation of the memory device 1200. The control signals and the data signals may be transmitted to the memory device 1200 through different input/output lines. The data signal may include a command, an address, or data. The control signal may be used to distinguish sections in which the data signals are input from each other.

The memory device 1200 may perform a program operation, a read operation, an erase operation, and the like, under the control of the controller 1100. The memory device 1200 may be implemented as a volatile memory device in which stored data disappears when power supply is interrupted or a non-volatile memory device in which stored data is maintained even when the power supply is interrupted. The memory device 1200 may be a semiconductor device having a structure as described above with reference to FIGS. 1A to 10. As an example, the semiconductor device may include a first memory cell array including a first source line, a first bit line, a first memory string connected between the first source line and the first bit line and including first memory cells, and first word lines connected to the first memory cells; a second memory cell array located over the first memory cell array and including a second source line, a second bit line, a second memory string connected between the second source line and the second bit line and including second memory cells, and second word lines connected to the second memory cells; a first interconnection structure including a first through via passing through the first memory cell array and commonly connected to the first bit line and the second bit line; a second interconnection structure including a second through via passing through the first memory cell array and commonly connected to the first word line and the second word line; a page buffer selectively accessing the first memory string or the second memory string through the first interconnection structure; and a row decoder commonly controlling the first word line and the second word line through the second interconnection structure.

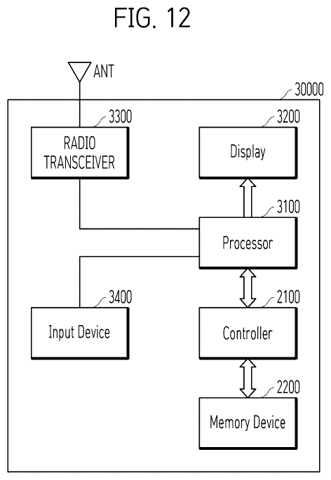

FIG. 12 is a simplified diagram of a memory system in accordance with an embodiment of the present invention.

Referring to FIG. 12, the memory system 30000 may be implemented as a cellular phone, a smartphone, a tablet PC, a personal computer (PC), a personal digital assistant (PDA), or a wireless communication device. The memory system 30000 may include a memory device 2200 and a controller 2100 capable of controlling an operation of the memory device 2200.

The controller 2100 may control a data access operation, such as a program operation, an erase operation, or a read operation, of the memory device 2200 under the control of a processor 3100.

Data programmed in the memory device 2200 may be output through a display 3200 under the control of the controller 2100.

A radio transceiver 3300 may transmit and receive radio signals through an antenna ANT. For example, the radio transceiver 3300 may change a radio signal received through the antenna ANT into a signal that may be processed by the processor 3100. Accordingly, the processor 3100 may process the signal output from the radio transceiver 3300 and transmit the processed signal to the controller 2100 or the display 3200. The controller 2100 may transmit the signal processed by the processor 3100 to the memory device 2200. In addition, the radio transceiver 3300 may change a signal output from the processor 3100 into a radio signal and output the changed radio signal to an external device through the antenna ANT. An input device 3400 is a device capable of inputting a control signal for controlling an operation of the processor 3100 or data to be processed by the processor 3100 and may be implemented as a pointing device such as a touch pad and a computer mouse, a keypad, or a keyboard. The processor 3100 may control an operation of the display 3200 so that data output from the controller 2100, data output from the radio transceiver 3300, or data output from the input device 3400 may be output through the display 3200.

According to an embodiment, the controller 2100 capable of controlling the operation of the memory device 2200 may be implemented as a portion of the processor 3100 or implemented as a separate chip from the processor 3100.

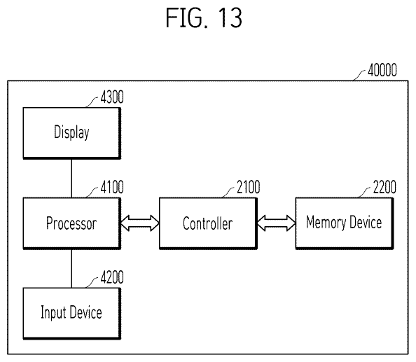

FIG. 13 is a simplified diagram of a memory system in accordance with an embodiment of the present invention.

Referring to FIG. 13, the memory system 40000 may be implemented as a PC, a tablet PC, a net-book, an e-reader, a PDA, a portable multimedia player (PMP), an MP3 player, or an MP4 player.

The memory system 40000 may include a memory device 2200 and a controller 2100 capable of controlling a data processing operation of the memory device 2200.

A processor 4100 may output data stored in the memory device 2200 through a display 4300 according to data entered through an input device 4200. For example, the input device 4200 may be implemented as a pointing device such as a touch pad or a computer mouse, a keypad, or a keyboard.

The processor 4100 may control an overall operation of the memory system 40000 and control an operation of the controller 2100. According to an embodiment, the controller 2100 capable of controlling the operation of the memory device 2200 may be implemented as a portion of the processor 4100 or implemented as a separate chip from the processor 4100.

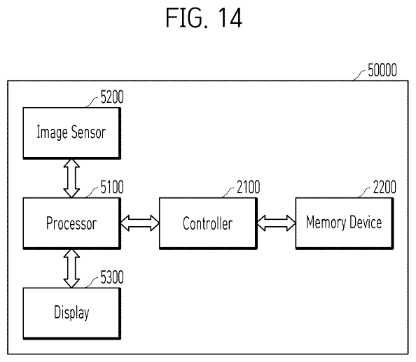

FIG. 14 is a simplified diagram of a memory system in accordance with an embodiment of the present invention.

Referring to FIG. 14, the memory system 50000 may be implemented as an image processing device such as a digital camera, a cellular phone with a digital camera, a smartphone with a digital camera, or a tablet PC with a digital camera.

The memory system 50000 may include a memory device 2200 and a controller 2100 capable of controlling a data processing operation, such as a program operation, an erase operation, or a read operation, of the memory device 2200.

An image sensor 5200 of the memory system 50000 may convert optical images into digital signals, and the converted digital signals may be transmitted to a processor 5100 or the controller 2100. Under the control of the processor 5100, the converted digital signals may be output through a display 5300 or stored in the memory device 2200 through the controller 2100. In addition, data stored in the memory device 2200 may be output through the display 5300 under the control of the processor 5100 or the controller 2100.

According to an embodiment, the controller 2100 capable of controlling the operation of the memory device 2200 may be implemented as a portion of the processor 5100 or implemented as a separate chip from the processor 5100.

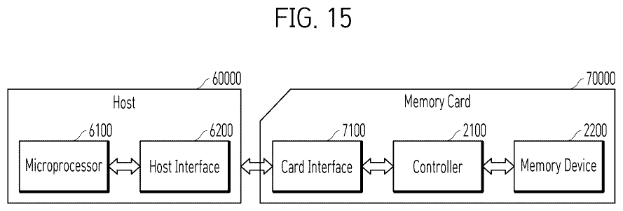

FIG. 15 is a simplified diagram of a memory system in accordance with an embodiment of the present invention.

Referring to FIG. 15, the memory system 70000 may be implemented as a memory card or a smart card. The memory system 70000 may include a memory device 2200, a controller 2100, and a card interface 7100 operatively coupled to each other.

The controller 2100 may control data exchange between the memory device 2200 and the card interface 7100. According to an embodiment, the card interface 7100 may be a secure digital (SD) card interface or a multi-media card (MMC) interface, but the embodiments are not limited thereto.

The card interface 7100 may interface data exchange between a host 60000 and the controller 2100 according to a protocol of the host 60000. According to an embodiment, the card interface 7100 may support a universal serial bus (USB) protocol or an interchip (IC)-USB protocol. Here, the card interface 7100 may refer to hardware capable of supporting a protocol used by the host 60000, software mounted in the hardware, or a signal transmission method.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 2200 through the card interface 7100 and the controller 2100 under the control of a microprocessor 6100.

Although various embodiments of the present disclosure have been described above with reference to the accompanying drawings, this is only for illustrating the various embodiments according to the technical concepts of the present disclosure. Also, the embodiments of the present disclosure are not limited only to the above embodiments. Various types of substitutions, modifications, changes, and combinations for the embodiments may be made by those skilled in the art, to which the present disclosure pertains, without departing from the technical concepts and scope of the present disclosure as defined in the following claims, and it should be construed that these substitutions, modifications, changes, and combinations belong to the scope of the present disclosure. Furthermore, the embodiments may be combined to form additional embodiments.

What is claimed is:

1. A semiconductor device comprising:
a first memory cell array including a first source line, a first bit line, a first memory string connected between the first source line and the first bit line, the first memory string including first memory cells, and first word lines connected to the first memory cells;
a second memory cell array located over the first memory cell array and including a second source line, a second bit line, a second memory string connected between the second source line and the second bit line, the second memory string including second memory cells, and second word lines connected to the second memory cells;
a first interconnection structure including a first through via passing through the first memory cell array and commonly connected to the first bit line and the second bit line;
a second interconnection structure including a second through via passing through the first memory cell array and commonly connected to the first word line and the second word line;
a page buffer selectively accessing the first memory string or the second memory string through the first interconnection structure; and
a row decoder commonly controlling the first word line and the second word line through the second interconnection structure.

2. The semiconductor device of claim 1, wherein the first memory cell array comprises:
a first gate structure including the first word lines;
the first bit line located under the first gate structure; and
the first source line located over the first gate structure,
wherein the first through via passes through the first gate structure and the first source line.

3. The semiconductor device of claim 2, wherein the second memory cell array comprises:
a second gate structure including the second word lines;
the second bit line located under the second gate structure; and
the second source line located over the second gate structure.

4. The semiconductor device of claim 3, further comprising a third memory cell array located over the second memory cell array and including a third source line, a third bit line, a third memory string connected between the third source line and the third bit line and including third memory cells, and third word lines connected to the third memory cells.

5. The semiconductor device of claim 4, wherein the first interconnection structure further includes a third through via passing through the second memory cell array and connecting the second bit line and the third bit line to each other, and
the second interconnection structure further includes a fourth through via passing through the second memory cell array and connecting the second word lines and the third word lines to each other.

6. The semiconductor device of claim 2, wherein the second memory cell array comprises:
a second gate structure including the second word lines;
the second source line located under the second gate structure; and
the second bit line located over the second gate structure.

7. The semiconductor device of claim 6, wherein the first interconnection structure further includes a third through via passing through the second memory cell array and connecting the second bit line and the first through via to each other, and
the second interconnection structure further includes a fourth through via passing through the second memory cell array and connecting the second word lines and the second through via to each other.

8. The semiconductor device of claim 7, wherein the first through via and the third through via are directly connected to each other, and
the second through via and the fourth through via are directly connected to each other.

9. The semiconductor device of claim 1, wherein the first memory cell array comprises:
a first gate structure including the first word lines;
the first source line located under the first gate structure; and
the first bit line located over the first gate structure.

10. The semiconductor device of claim 9, wherein the second memory cell array comprises:
a second gate structure including the second word lines;
the second bit line located under the second gate structure; and
the second source line located over the second gate structure.

11. The semiconductor device of claim 1, wherein the first interconnection structure includes a bonding pad electrically connecting the first memory cell array and the second memory cell array to each other.

12. The semiconductor device of claim 1, wherein the first memory string and the second memory string are included in the same memory block.

13. The semiconductor device of claim 1, further comprising a third interconnection structure including a third through via passing through the first memory cell array and commonly connected to the first source line and the second source line.

14. The semiconductor device of claim 13, further comprising a source control circuit commonly controlling the first source line and the second source line through the third interconnection structure.

15. The semiconductor device of claim 1, further comprising a source control circuit individually controlling the first source line and the second source line.

16. A semiconductor device comprising:
a first gate structure including stacked first word lines;
a second gate structure located over the first gate structure and including stacked second word lines;
a first bit line located under the first gate structure;
a first source line located between the first gate structure and the second gate structure;
a second bit line located between the first source line and the second gate structure;
a second source line located over the second gate structure;
a first through via passing through the first source line and the first gate structure and connecting the first bit line and the second bit line to each other;
second through vias passing through the first gate structure and connecting the first word lines and the second word lines to each other;
a page buffer commonly connected to the first bit line and the second bit line through the first through via; and
a row decoder commonly controlling the first word lines and the second word lines through the second through vias.

17. The semiconductor device of claim 16, further comprising:
a third gate structure located over the second gate structure and including stacked third word lines;
a third bit line located between the third gate structure and the second gate structure; and
a third through via passing through the second gate structure and connecting the second bit line and the third bit line to each other.

18. The semiconductor device of claim 17, further comprising fourth through vias passing through the second gate structure and connecting the second word lines and the third word lines to each other.

19. The semiconductor device of claim 16, further comprising a third through via passing through a dummy region of the first gate structure and connecting the first source line and the second source line to each other.

20. The semiconductor device of claim 19, further comprising a source control circuit commonly controlling the first source line and the second source line through the third through via.

21. The semiconductor device of claim 16, further comprising a source control circuit individually controlling the first source line and the second source line.

22. A semiconductor device comprising:
a first memory cell array including a first source line, a first bit line, a first memory string connected between the first source line and the first bit line and including first memory cells, and first word lines connected to the first memory cells;
a second memory cell array electrically connected to the first memory cell array and including a second source line, a second bit line, a second memory string connected between the second source line and the second bit line and including second memory cells, and second word lines connected to the second memory cells; and
a peripheral circuit electrically connected to the first memory cell array through a bonding pad and including a page buffer selectively accessing the first memory string or the second memory string, a row decoder commonly controlling the first word lines and the second word lines, and a source control circuit commonly controlling the first source line and the second source line.
